(19) United States
(12) Patent Application Publication
(10) Pub. No.: US 2026/0214848 A1
(43) Pub. Date: Jul. 23, 2026

(54) TWO-PHASE COOLING SYSTEM AND FLOW DIRECTOR THEREOF

(71) Applicant: WE SOLUTIONS TECHNOLOGY CO., LTD, Taoyuan City (TW)

(72) Inventors: CHUNG-PENG HUANG, Taoyuan City (TW); KUAN-LIN CHEN, Taoyuan City (TW); CHUN-CHING KUO, Taoyuan City (TW); KUN-DA WU, Taoyuan City (TW); CHUNG-EN LEE, Taoyuan City (TW)

(73) Assignee: WE SOLUTIONS TECHNOLOGY CO., LTD, Taoyuan City (TW)

(21) Appl. No.: 19/086,160

(22) Filed: Mar. 21, 2025

(30) Foreign Application Priority Data
Jan. 21, 2025 (TW) 114102526

(51) Int. Cl. H05K 7/20

(52) U.S. Cl. CPC H05K 7/20318; H05K 7/20327

(57) ABSTRACT

A two-phase cooling system is provided, including a closed tank; a condensing module, having a plurality of condenser tubes, where the plurality of condenser tubes are located above an interior of the closed tank and arranged longitudinally at intervals; and a plurality of flow directors, where each of the flow directors has at least one inclined plate and at least one engagement portion, the engagement portion is connected to the inclined plate, the engagement portion is engaged with any one of the condenser tubes or the closed tank, and the inclined plate extends between two adjacent condenser tubes.

### CROSS-REFERENCE TO RELATED APPLICATION

This non-provisional application claims priority under 35 U.S.C. § 119(a) on Patent Application No(s).114102526 filed in Taiwan, R.O.C. on Jan. 21, 2025, the entire contents of which are hereby incorporated by reference.

### BACKGROUND OF THE INVENTION

### Field of the Invention

The present disclosure relates to a cooling system and a component thereof, and in particular, to a two-phase cooling system and a flow director thereof.

### Description of the Related Art

With a rapid increase in power and heat flux density of heat generating components of computer computing-related electronic elements, immersion cooling is one of the relatively efficient cooling technologies currently to quickly reduce heat generated by electronic computing elements.

Generally speaking, a conventional two-phase cooling system generally includes a closed tank and a condensing module. The closed tank contains a liquid coolant (for example, perfluoro-ketone, whose boiling point approaches 50℃) inside, and the electronic computing elements are immersed in the liquid coolant. The condensing module is arranged at an upper position inside the closed tank, and has a plurality of condenser tubes arranged longitudinally at intervals. Accordingly, when the electronic computing element operates at an elevated temperature, the liquid coolant around the electronic computing element absorbs heat, boils, and changes to a gaseous state. The coolant in the gaseous state may go up, be condensed back to the liquid state when contacting the plurality of condenser tubes at a relatively low temperature, and drip back to a lower space, thereby achieving an effect of circulation of the coolant without the need to provide additional resources or pump power for heat dissipation, which may effectively reduce electricity consumption and carbon emissions of related industries.

### BRIEF SUMMARY OF THE INVENTION

However, in a conventional two-phase cooling system, if an electronic computing element operates at a rapidly elevated temperature in a short time, a large amount of liquid coolant quickly vaporizes, and a large amount of gaseous coolant is produced. In this case, a large amount of liquid coolant is continuously generated by tube walls of a plurality of condenser tubes through condensation, and the large amount of liquid coolant almost flows downward under the force of gravity in a state of forming a water curtain. In this way, in addition to the liquid coolant generated by the condenser tube located below through condensation, the condenser tube is also continuously splashed by a liquid coolant generated by an upper condenser tube, so that a water film with a relatively small heat conduction coefficient is easily generated on a tube wall of the lower condenser tube, resulting in a reduction in condensation efficiency of the lower condenser tube, and causing a significant negative impact on condensation efficiency of the entire condensing module.

In view of the above shortcomings of the foregoing conventional technology, the inventor felt that the technology was not perfect, and therefore devoted all attention to carefully study and overcome the shortcomings, and then developed a two-phase cooling system. A condensing module of the two-phase cooling system is equipped with a flow director, so as to effectively prevent a tube wall of a condenser tube from forming a water film.

To achieve the foregoing objective and another objective, the present disclosure provides a two-phase cooling system, including a closed tank; a condensing module, having a plurality of condenser tubes, where the plurality of condenser tubes are located above an interior of the closed tank and arranged longitudinally at intervals; and a plurality of flow directors, where each of the flow directors has at least one inclined plate and at least one engagement portion, the engagement portion is connected to the inclined plate, the engagement portion is engaged with any one of the condenser tubes or the closed tank, and the inclined plate extends between two adjacent condenser tubes.

In the foregoing two-phase cooling system, the inclined plate has a liquid outlet end edge, and the liquid outlet end edge of the inclined plate may be relatively adjacent to a tank wall of the closed tank.

In the foregoing two-phase cooling system, the inclined plate has a liquid outlet end edge, the condenser tube located below has an end edge on a same side as the liquid outlet end edge, and the liquid outlet end edge of the inclined plate may protrude beyond the end edge.

In the foregoing two-phase cooling system, the flow director may have a plurality of inclined plates, and the engagement portion may be simultaneously connected to the plurality of inclined plates.

In the foregoing two-phase cooling system, the engagement portion may have a connecting sheet, a hook, and an abutting sheet, the connecting sheet may be connected to the plurality of inclined plates, the hook may be connected to the connecting sheet, the abutting sheet may be connected to a liquid outlet end edge of one of the inclined plates, the hook may hook one of the condenser tubes, and the abutting sheet may block an inner side or an outer side of another condenser tube.

In the foregoing two-phase cooling system, the connecting sheet may abut against an inner side of each of the plurality of condenser tubes, and the abutting sheet may abut against an outer side of one of the condenser tubes, or the connecting sheet may abut against an outer side of each of the plurality of condenser tubes, and the abutting sheet may abut against an inner side of one of the condenser tubes.

In the foregoing two-phase cooling system, the engagement portion may have at least one connecting sheet and at least one first protrusion, the connecting sheet may be connected to the plurality of inclined plates, the first protrusion may be connected to and protrude from a lower surface of each of the inclined plates, and the first protrusion may abut against a lower condenser tube.

In the foregoing two-phase cooling system, an inclined plate may be configured between any two of the plurality of condenser tubes.

In the foregoing two-phase cooling system, the flow director may have only a single inclined plate.

In the foregoing two-phase cooling system, the plurality of condenser tubes may be divided into an inner ring condenser tube and an outer ring condenser tube. The outer ring condenser tube is located on a periphery of the inner ring condenser tube. A plurality of inclined plates may be arranged. The engagement portion may have at least one connecting sheet, at least one first protrusion, and at least one second protrusion. The connecting sheet may be connected to the plurality of inclined plates. The first protrusion and the second protrusion may be both connected to and protrude from a lower surface of each of the inclined plates. The first protrusion may abut against a lower inner ring condenser tube, and the second protrusion may abut against a lower outer ring condenser tube.

In the foregoing two-phase cooling system, the inclined plate may be connected to a flow guide sheet extending downward at a lower inclined position.

The present disclosure further provides a flow director, which is adapted to be configured in a two-phase cooling system. The two-phase cooling system has a closed tank and a condensing module. The condensing module has a plurality of condenser tubes located above an interior of the closed tank and arranged longitudinally at intervals. The flow director includes at least one inclined plate and at least one engagement portion. The engagement portion is connected to the inclined plate. The engagement portion is adapted to be engaged with any one of the condenser tubes or the closed tank, and the inclined plate is adapted to extend between two adjacent condenser tubes.

In the foregoing flow director, the inclined plate has a liquid outlet end edge, and the liquid outlet end edge may be relatively adjacent to a tank wall of the closed tank.

In the foregoing flow director, the inclined plate has a liquid outlet end edge, the condenser tube located below has an end edge on a same side as the liquid outlet end edge, and the liquid outlet end edge of the inclined plate may be adapted to protrude beyond the end edge.

In the foregoing flow director, a plurality of inclined plates may be arranged, and the engagement portion may be simultaneously connected to the plurality of inclined plates.

In the foregoing flow director, the engagement portion may have a connecting sheet, a hook, and an abutting sheet, the connecting sheet may be connected to the plurality of inclined plates, the hook may be connected to the connecting sheet, the abutting sheet may be connected to a liquid outlet end edge of one of the inclined plates, the hook may be adapted to hook one of the condenser tubes, and the abutting sheet may be adapted to block an inner side or an outer side of another condenser tube.

In the foregoing flow director, the connecting sheet may be adapted to abut against an inner side of each of the plurality of condenser tubes, and the abutting sheet may be adapted to abut against an outer side of one of the condenser tubes, or the connecting sheet may be adapted to abut against an outer side of each of the plurality of condenser tubes, and the abutting sheet may be adapted to abut against an inner side of one of the condenser tubes.

In the foregoing flow director, the engagement portion may have at least one connecting sheet and at least one first protrusion, the connecting sheet may be connected to the plurality of inclined plates, the first protrusion may be connected to and protrude from a lower surface of each of the inclined plates, and the first protrusion may be adapted to abut against a lower condenser tube.

In the foregoing flow director, a single inclined plate is arranged.

In the foregoing flow director, the plurality of condenser tubes of the condensing module may be divided into an inner ring condenser tube and an outer ring condenser tube. The outer ring condenser tube is located on a periphery of the inner ring condenser tube. A plurality of inclined plates may be arranged. The engagement portion may have at least one connecting sheet, at least one first protrusion, and at least one second protrusion. The connecting sheet may be connected to the plurality of inclined plates. The first protrusion and the second protrusion may be both connected to and protrude from a lower surface of each of the inclined plates. The first protrusion may be adapted to abut against a lower inner ring condenser tube, and the second protrusion may be adapted to abut against a lower outer ring condenser tube.

In the foregoing flow director, the inclined plate may be connected to a flow guide sheet extending downward at a lower inclined position.

Based on this, in the two-phase cooling system of the present disclosure, the flow director may be arranged, so that the liquid coolant generated by the upper condenser tube through condensation may be directed by the inclined plate towards a lateral side of the lower condenser tube, and the upper half surface of the lower condenser tube is less susceptible to continuous splashing of the liquid coolant. Therefore, the water film is not easily generated, thereby ensuring that the condensing module can fully utilize desirable condensation efficiency.

### BRIEF DESCRIPTION OF THE DRAWINGS

FIG. 1 is a three-dimensional schematic exploded view of an embodiment of a two-phase cooling system according to the present disclosure.

FIG. 2 is a three-dimensional schematic exploded view of a condensing module and a plurality of flow directors according to an embodiment of the present disclosure.

FIG. 3 is a schematic diagram of a three-dimensional combination of a condensing module and a plurality of flow directors according to an embodiment of the present disclosure.

FIG. 4 is a schematic top view of a condensing module and a plurality of flow directors according to an embodiment of the present disclosure.

FIG. 5 is a schematic diagram of a cross-sectional structure taken along line A-A in FIG. 4.

FIG. 6 is an enlarged view of part B in FIG. 5.

FIG. 7 is a schematic structural diagram of another embodiment of a state in FIG. 6.

FIG. 8 is a schematic three-dimensional view of a flow director according to another embodiment of the present disclosure.

FIG. 9 is a three-dimensional schematic exploded view of a condensing module and a plurality of flow directors according to still another embodiment of the present disclosure.

FIG. 10 is a schematic three-dimensional view of the flow director shown in FIG. 9 from another perspective.

FIG. 11 is a schematic diagram of a partially enlarged cross-sectional structure of the condensing module and the flow directors shown in FIG. 9.

FIG. 12 is a schematic diagram of a partially enlarged cross-sectional structure of a condensing module and a flow director according to yet another embodiment of the present disclosure.

### DETAILED DESCRIPTION OF THE INVENTION

In order to fully understand the purpose, features, and effects of the present disclosure, the present disclosure is described in detail by means of the following specific embodiments and the accompanying drawings. The description is as follows:

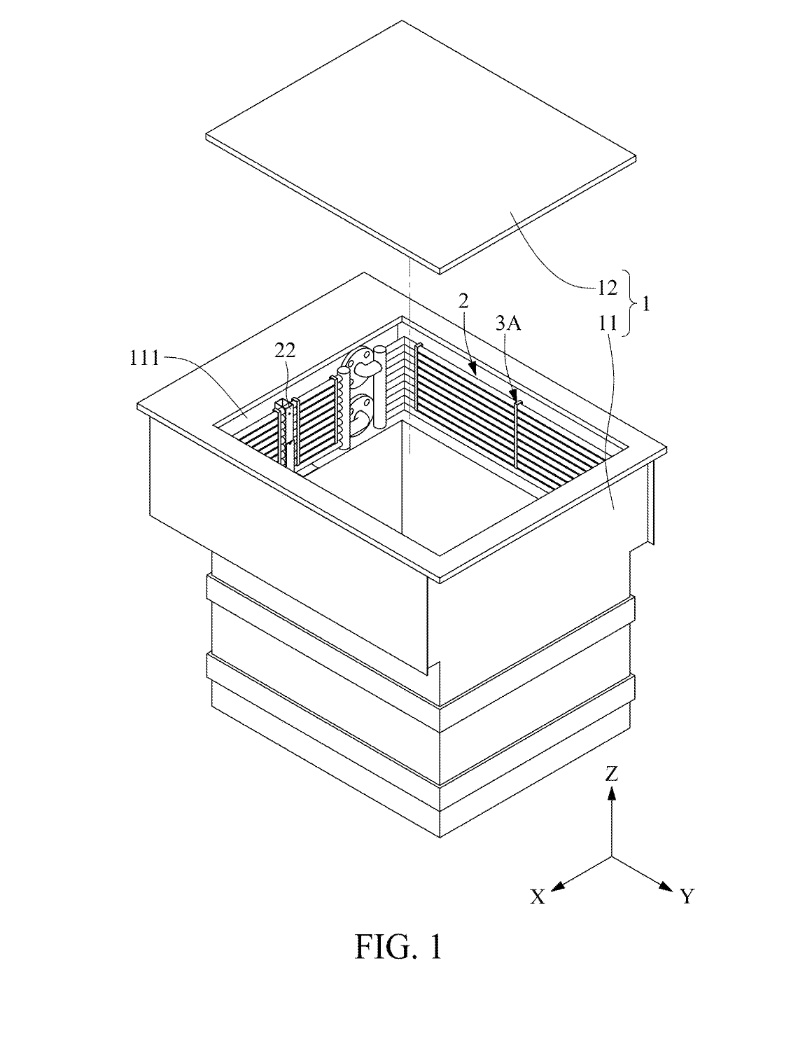

Referring to FIG. 1, FIG. 1 is a preferred embodiment of a two-phase cooling system according to the present disclosure. The two-phase cooling system includes a closed tank 1, a condensing module 2, and a plurality of flow directors 3A.

The closed tank 1 has a tank body 11 and a cover 12. The tank body 11 may contain a liquid coolant inside, and is configured for an electronic computing element to be firmly mounted and immersed in the liquid coolant. The cover 12 may seal an opening of the tank body 11, to prevent the coolant from leaking. A form of the closed tank 1 is not limited in the present disclosure, and is based on the principle of achieving the above function. Therefore, the form is not limited to the form disclosed in the drawings.

The condensing module 2 has a plurality of condenser tubes 21. The plurality of condenser tubes 21 are located above an interior of the closed tank 1 and arranged longitudinally at intervals. In an embodiment of the present disclosure, the plurality of condenser tubes 21 may be selectively positioned at a position near the top of the tank body 11 through a plurality of fixing brackets 22 engaged with the tank body 11, so that the plurality of condenser tubes 21 are close to, but not touch, a tank wall 111 of the tank body 11.

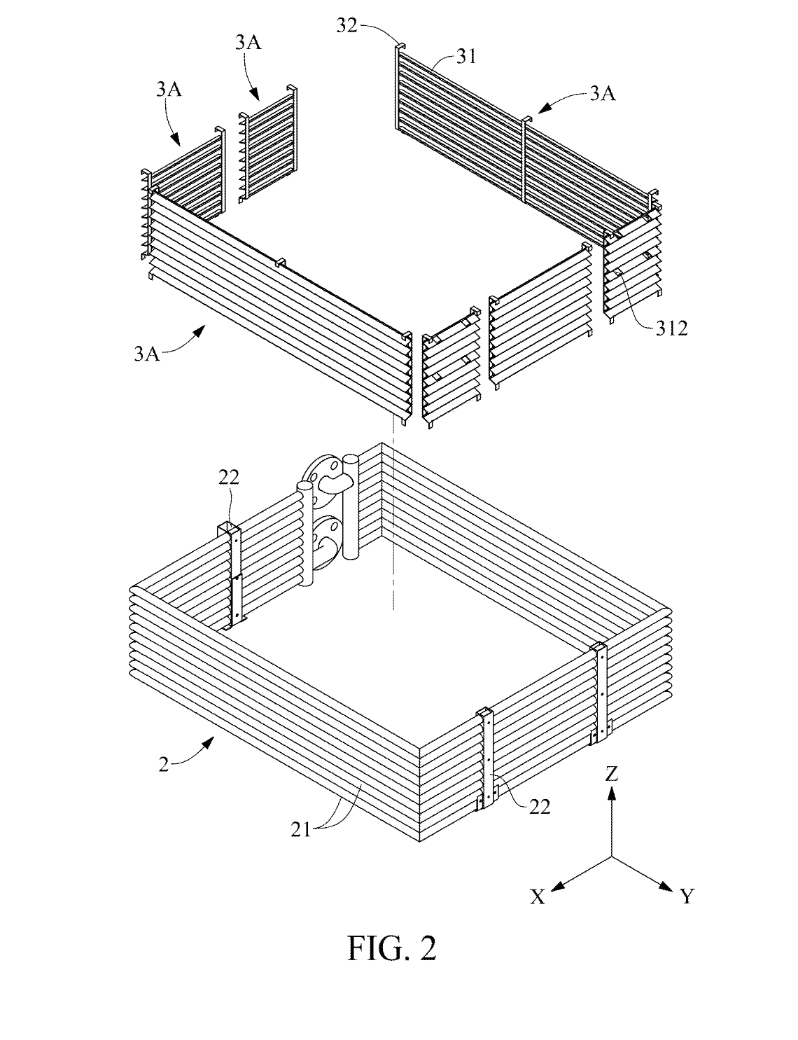

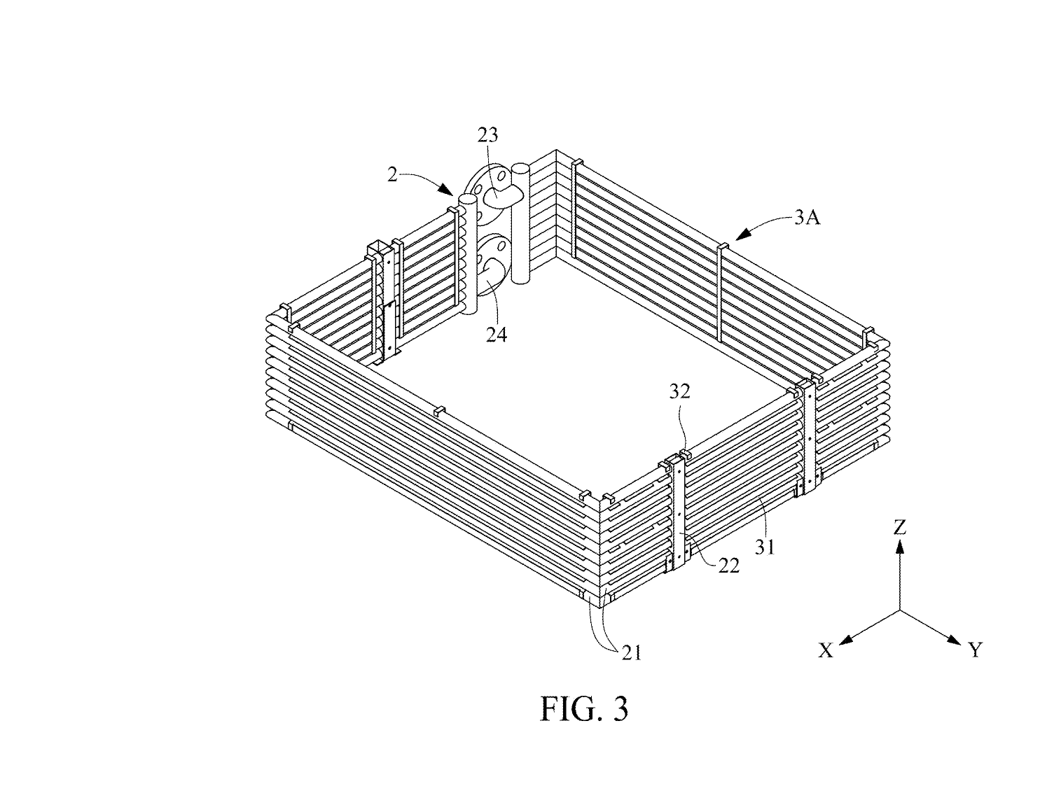

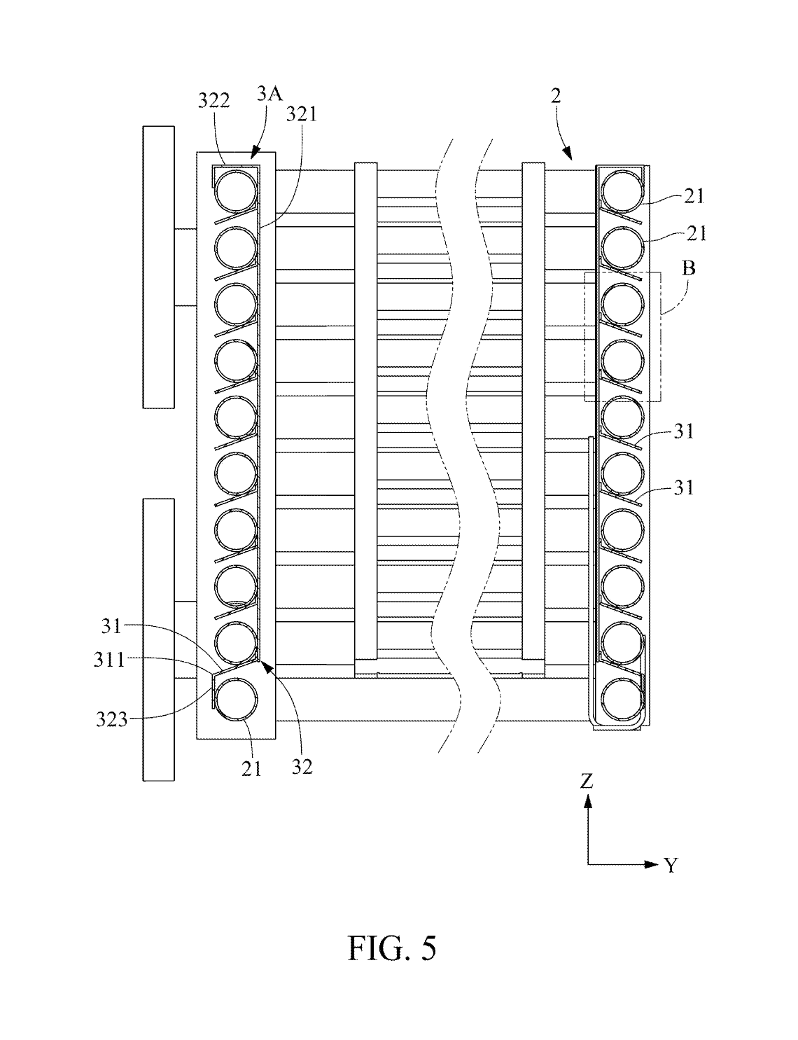

Referring to FIG. 2 and FIG. 3, in this embodiment, the plurality of condenser tubes 21 may be respectively shaped like rings. Head ends of the plurality of condenser tubes 21 are connected, and tail ends thereof are also connected. The condensing module 2 has a circulating liquid input portion 23 and a circulating liquid output portion 24. The head ends of the plurality of condenser tubes 21 are connected to one of the circulating liquid input portion 23 and the circulating liquid output portion 24, and the tail ends of the plurality of condenser tubes 21 are connected to the other of the circulating liquid input portion and the circulating liquid output portion. Sectional shapes or sizes of the plurality of condenser tubes 21 may be the same or different, which is not limited in the present disclosure and not limited to circular tubes disclosed in the drawings (refer to FIG. 5).

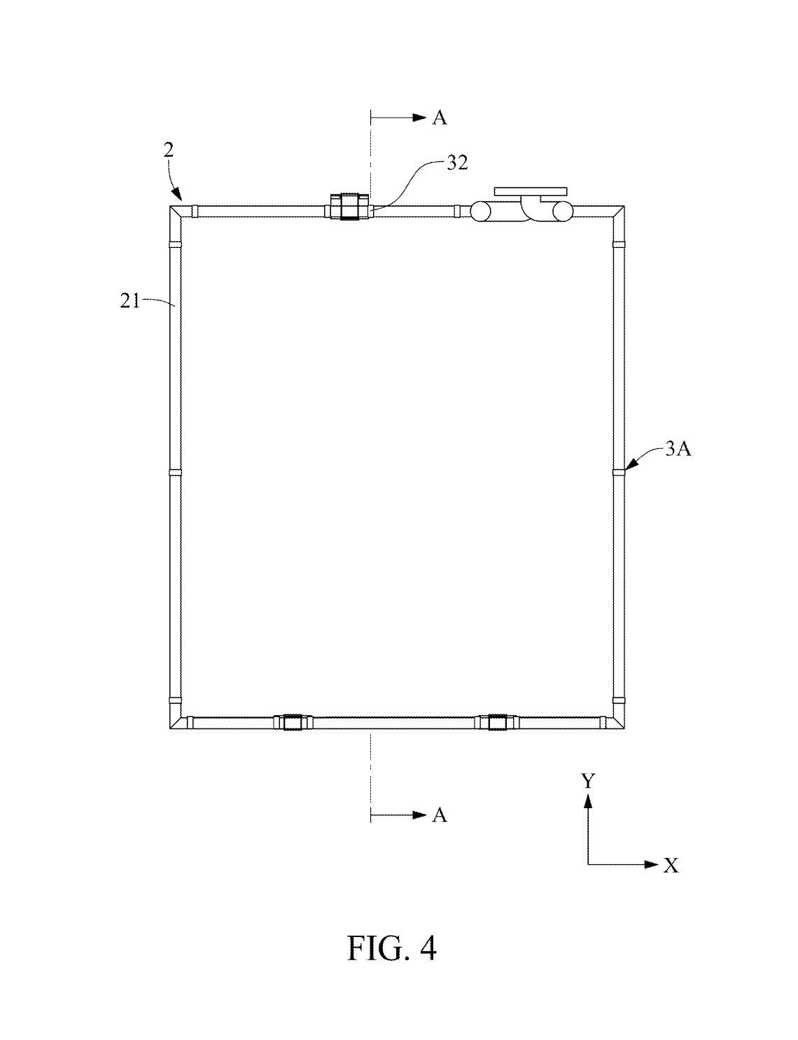

Referring to FIG. 2, FIG. 4, and FIG. 5, each of the flow directors 3A has at least one inclined plate 31 and at least one engagement portion 32. The engagement portion 32 is connected to the inclined plate 31. The engagement portion 32 is engaged with any one of the condenser tubes 21 or the tank body 11, so that the inclined plate 31 can extend between two adjacent condenser tubes 21.

Accordingly, in the two-phase cooling system of this embodiment, a liquid coolant generated by an upper condenser tube 21 through condensation may be directed by the inclined plate 31 towards a lateral side of a lower condenser tube 21, instead of splashing in large amounts onto the lower condenser tube 21. Since an upper half surface of the lower condenser tube 21 may keep most or all of the surface from being continuously splashed by the liquid coolant, a water film is not easily formed on a tube wall of the lower condenser tube 21. In this way, a problem of a significant reduction in condensation efficiency of the entire condensing module 2 as a result of generation of a water film before can be significantly alleviated, so that the condensing module 2 can fully utilize desirable condensation efficiency.

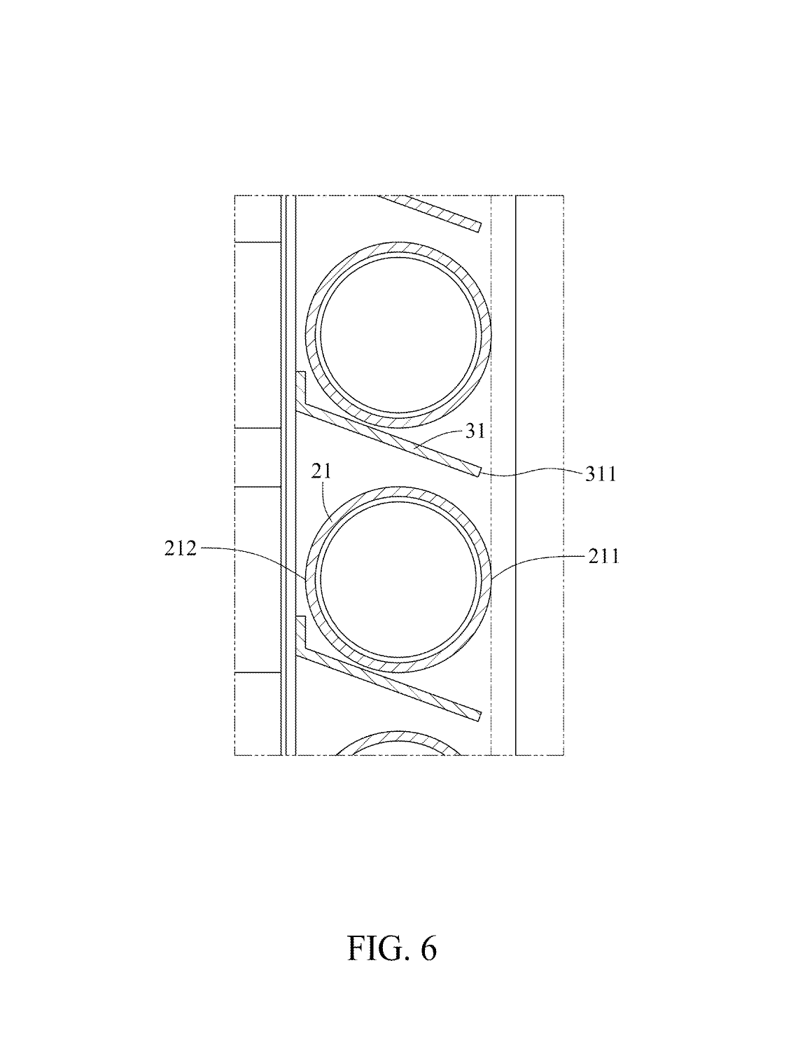

The plurality of circular condenser tubes 21 may be enclosed to form an internal space. In the present disclosure, a direction facing the internal space is defined as an inner side, and a direction facing away from the internal space is defined as an outer side. Referring to FIG. 5 and FIG. 6, the inclined plate 31 has a liquid outlet end edge 311. The liquid outlet end edge 311 may be located at a lowest position of the inclined plate 31, so that most of the liquid coolant received by the inclined plate 31 can flow out of the inclined plate 31 through the liquid outlet end edge 311. An inclination direction of the inclined plate 31 is not limited in the present disclosure. To be specific, the liquid coolant may flow out to the inner side or the outer side of each of the plurality of condenser tubes 21.

It is worth mentioning that since most of gaseous coolant flows upward from the inner side of the plurality of condenser tubes 21, it is preferred that the liquid coolant may be delivered to the outer side of the plurality of condenser tubes 21, so as to avoid affecting efficiency of the gaseous coolant contacting the plurality of condenser tubes 21. In other words, in an embodiment of the present disclosure, it is preferred that the liquid outlet end edge 311 of the inclined plate 31 is closer to the tank wall 111 of the tank body 11 than another side. In this way, even if an amount of liquid coolant delivered to the outer side is large enough to form a water curtain, the efficiency of the gaseous coolant contacting the plurality of condenser tubes 21 is not greatly affected.

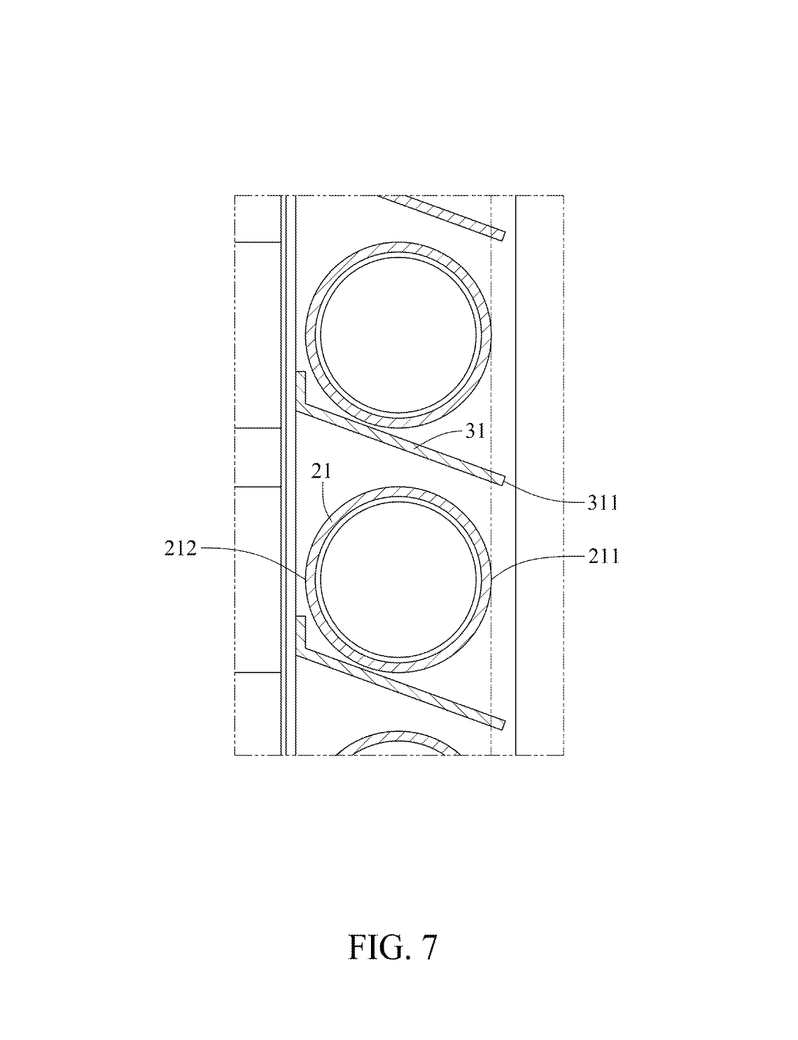

In addition, the condenser tube 21 located below has an end edge on the same side as the liquid outlet end edge 311. In other words, when the inclined plate 31 delivers the liquid coolant to the outer side, the end edge is an outer end edge 211 of the lower condenser tube 21. When the inclined plate 31 delivers the liquid coolant to the inner side, the end edge is an inner end edge 212 of the lower condenser tube 21. In an embodiment of the present disclosure, the liquid outlet end edge 311 of the inclined plate 31 may be extended as far as possible to the inner side or the outer side of the condenser tube 21 without affecting assembly, to reduce a range of the upper half of the lower condenser tube 21 onto which the liquid coolant that is directed out is splashed. Preferably, as shown in FIG. 7, the liquid outlet end edge 311 of the inclined plate 31 protrudes beyond the outer end edge 211 of the condenser tube 21 located below. In this way, the entire upper half of the lower condenser tube 21 may be less susceptible to continuous splashing of the liquid coolant, so that the water film is not formed on the tube wall of the lower condenser tube 21, and the lower condenser tube 21 can maintain a larger area where the gaseous coolant can be condensed efficiently, thereby improving the condensation efficiency of the condensing module 2. In an embodiment in which the liquid coolant is delivered to the inner side, it is preferred to allow the liquid outlet end edge 311 of the inclined plate 31 to protrude beyond the inner end edge 212 of the condenser tube 21 located below.

Moreover, referring to FIG. 2, FIG. 4, and FIG. 5 again, the form of the flow director 3A is not limited in the present disclosure, which may be adjusted based on different requirements such as a quantity of condenser tubes 21 and assembly or condensation efficiency. For example, in the embodiment shown in FIG. 2, the flow director 3A may have a plurality of inclined plates 31, and the engagement portion 32 may be simultaneously connected to the plurality of inclined plates 31, so that the plurality of inclined plates 31 may be mounted together between the plurality of condenser tubes 21 and do not need to be mounted one by one, which may improve the assembly efficiency.

In addition, in the embodiment shown in FIG. 5, an inclined plate 31 is configured between any two adjacent condenser tubes 21, which may greatly reduce negative impact of the water film to the greatest extent. However, the present disclosure is not limited to this form. In another possible embodiment, the plurality of inclined plates 31 may also be arranged at intervals. For example, the plurality of inclined plates 31 are arranged below an odd-numbered or even-numbered condenser tubes 21 counted from the top. Alternatively, an inclined plate 31 is arranged between any two adjacent condenser tubes 21 in the lower half, and no inclined plate 31 is arranged between the plurality of condenser tubes 21 in the upper half. Alternatively, the plurality of inclined plates are configured in any other form.

Referring to FIG. 2 again, the form of the flow director 3A may further vary depending on a condition of a position where the flow director is to be mounted. For example, at a position corresponding to the plurality of fixing brackets 22, the inclined plate 31 may be in a short form, and at a position without the plurality of fixing brackets 22, the inclined plate 31 may be in a long form. In addition, a hole 312 may further be provided at a position where interference may occur on the inclined plate 31 based on an environment of the mounting position.

Moreover, referring to FIG. 2 and FIG. 5, the form of the engagement portion 32 is not limited in the present disclosure. In an embodiment of the present disclosure, the engagement portion 32 may have a connecting sheet 321, a hook 322, and an abutting sheet 323. The connecting sheet 321 is connected to the plurality of inclined plates 31. The hook 322 is connected to the connecting sheet 321, and the abutting sheet 323 may be connected to a liquid outlet end edge 311 of one of the inclined plates 31. In this way, during mounting of the flow director 3A, the flow director 3A may be inclined first, so that the abutting sheet 323 and the plurality of inclined plates 31 may be aligned and inserted between the specified plurality of condenser tubes 21. Then the flow director 3A is straightened, and one of the condenser tubes 21 is hooked by the hook 322. In this case, the abutting sheet 323 may block a lateral side of the other condenser tube 21, so that the hook 322 and the abutting sheet 323 jointly maintain the entire flow director 3A to be stably hung on the plurality of condenser tubes 21. One of the abutting sheet 323 and the connecting sheet 321 may be located on the inner side of each of the plurality of condenser tubes 21, and the other is located on the outer side of each of the plurality of condenser tubes 21. For example, after the flow director 3A is assembled, the connecting sheet 321 may abut against the inner side of each of the plurality of condenser tubes 21, and the abutting sheet 323 abuts against an outer side of one of the condenser tubes 21, or vice versa, which can provide a more stable assembly effect.

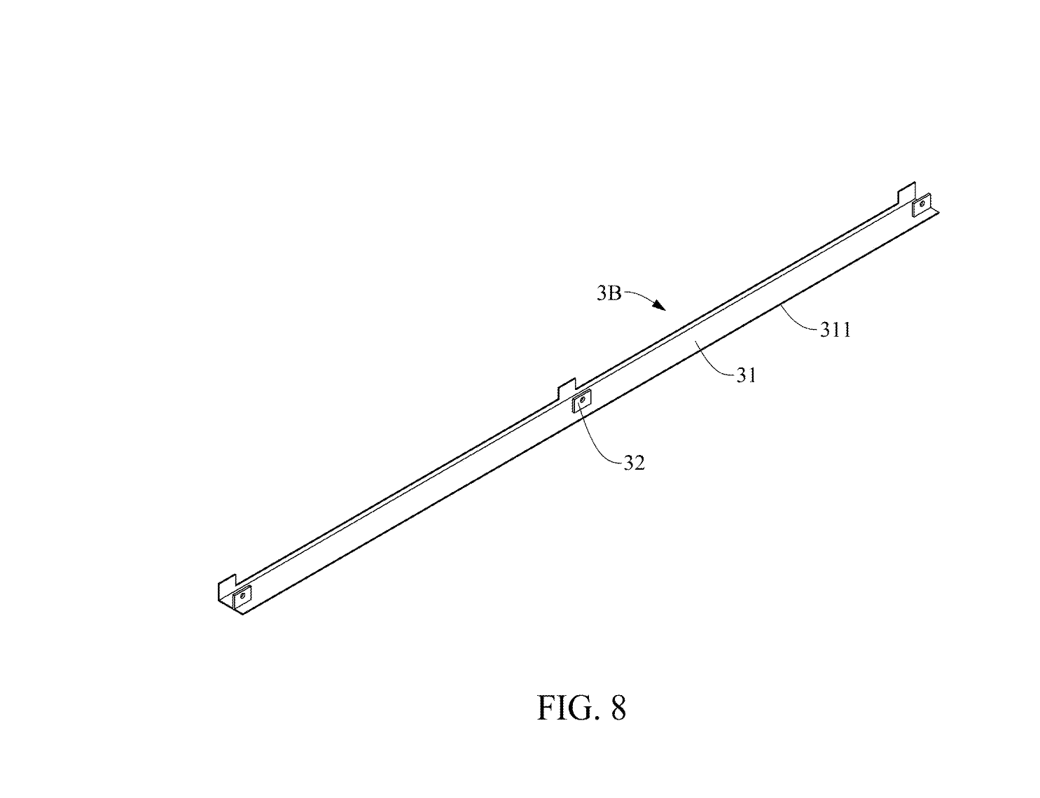

Referring to FIG. 8, FIG. 8 discloses a flow director 3B according to another embodiment of the present disclosure. In this embodiment, the flow director 3B may have only a single inclined plate 31, so that the flow director 3B may choose to arrange the inclined plate 31 between any two adjacent condenser tubes 21 as needed. In this way, the design freedom of configuring the plurality of flow directors 3B may be improved, so as to configure a required quantity of flow directors 3B based on different needs. A mounting position may also be increased, decreased, or changed at any time, and the flow directors may be disassembled and replaced independently to reduce maintenance costs. In addition, the engagement portion 32 of this embodiment may be, for example, a plurality of lug sets connected to the inclined plate 31, so that the engagement portion is clamped on the condenser tube 21 through each of the lug sets, or engaged with each of the lug sets through an engagement member such as a screw, a pin, or a hook, which is not limited in the present disclosure and not limited to the form disclosed in the accompanying drawings. The principle is that the engagement portion 32 does not interfere with an inclined plate 31 of another flow director 3B mounted above.

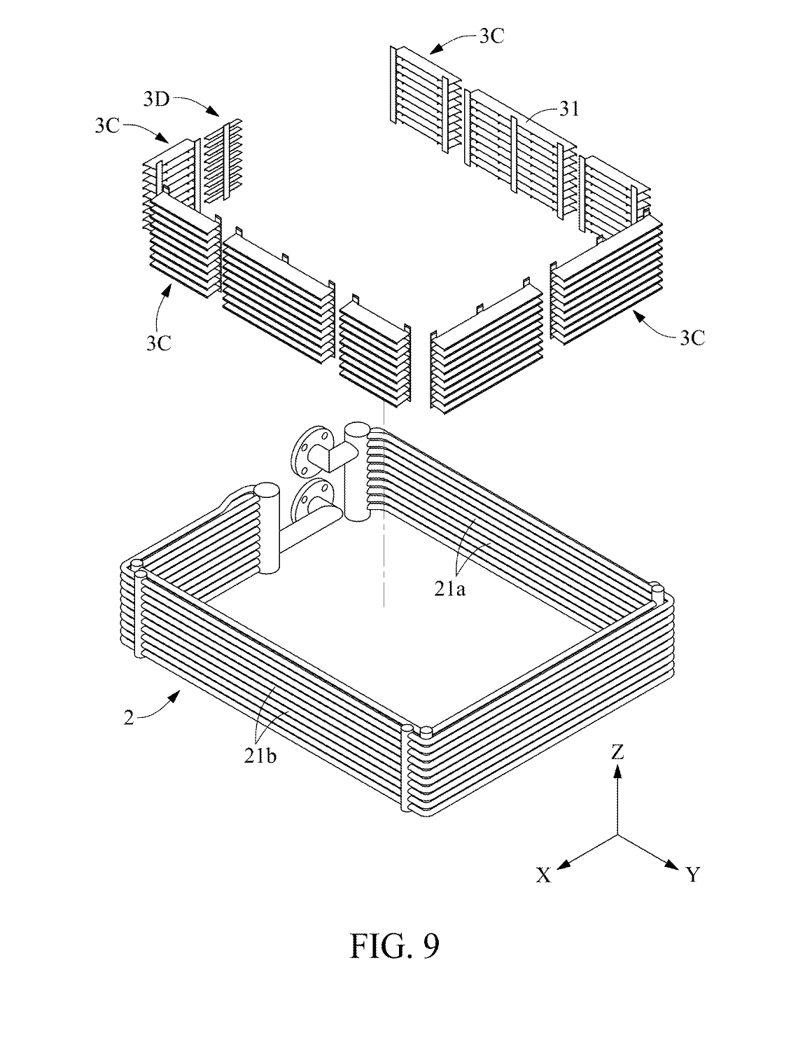

Referring to FIG. 9 to FIG. 11, a flow director 3C according to still another embodiment of the present disclosure is disclosed. In this embodiment, an inclined plate 31 of the flow director 3C may be connected to a flow guide sheet 313 extending downward at a lower inclined position. The flow guide sheet 313 may extend downward along a Z direction, or may extend in an inclined manner, and form an acute angle or an obtuse angle with a lower surface of the inclined plate 31, which is not limited in the present disclosure. In addition, for example and without limitation, in an embodiment of the present disclosure, the flow guide sheet 313 may be a portion formed by bending the liquid outlet end edge 311 of the inclined plate 31 downward. Alternatively, the flow guide sheet 313 may be connected to an end edge of the inclined plate 31 through a welding or fusion technology.

Through arrangement of the flow guide sheet 313, the liquid coolant may flow along a slope of the inclined plate 31 towards the flow guide sheet 313, leave the inclined plate 31 from an end edge of the flow guide sheet 313 (the liquid outlet end edge 311), and surely drip downward. However, no part of the liquid coolant flows back along the lower surface of the inclined plate 31 and drips onto the tube wall of the lower condenser tube 21 to generate a water film. Therefore, the effect of preventing the water film from being generated on the tube wall of the lower condenser tube 21 may be further improved.

It is worth mentioning that a structure of the flow guide sheet 313 is also applicable to the embodiments disclosed above. Therefore, the embodiments are not limited to the form disclosed in the accompanying drawings.

Moreover, in an embodiment of the present disclosure, the condensing module 2 includes a plurality of condenser tubes 21 arranged at intervals inside and outside. A double-ring condenser tube 21 is used as an example, which includes an inner ring condenser tube 21a and an outer ring condenser tube 21b. The outer ring condenser tube 21b is located on a periphery of the inner ring condenser tube 21a.

The flow director 3C may have a plurality of inclined plates 31 and at least one engagement portion 32. The engagement portion 32 may have at least one connecting sheet 321, at least one first protrusion 324, and at least one second protrusion 325. The connecting sheet 321 is connected to the plurality of inclined plates 31. The first protrusion 324 and the second protrusion 325 are both connected to and protrude from the lower surface of the inclined plate 31, and the first protrusion 324 is farther from the liquid outlet end edge 311 of the inclined plate 31 than the second protrusion 325. In this way, during mounting of the flow director 3C, the plurality of inclined plates 31 may be aligned and inserted between a plurality of condenser tubes 21 specified in a longitudinal direction. The first protrusion 324 abuts against the inner ring condenser tube 21a below, and the second protrusion 325 abuts against the outer ring condenser tube 21b below.

Accordingly, in this embodiment, through the first protrusion 324 and the second protrusion 325, the flow director 3C can be stably assembled onto the plurality of inner ring condenser tubes 21a and the plurality of outer ring condenser tubes 21b, and each of the inclined plates 31 can be spaced apart by a predetermined spacing from the inner ring condenser tube 21a and the outer ring condenser tube 21b below, so that the liquid coolant is less likely to flow to the tube wall of the condenser tube 21, which helps reduce the chance of forming a water film on the condenser tube 21.

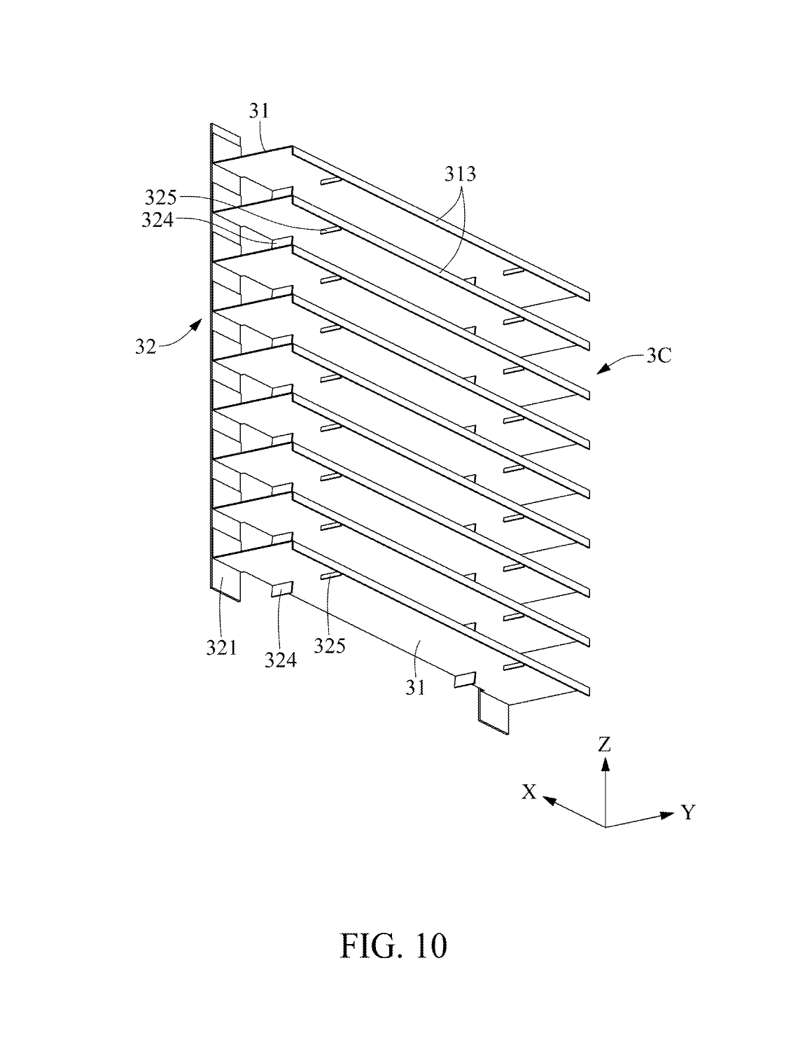

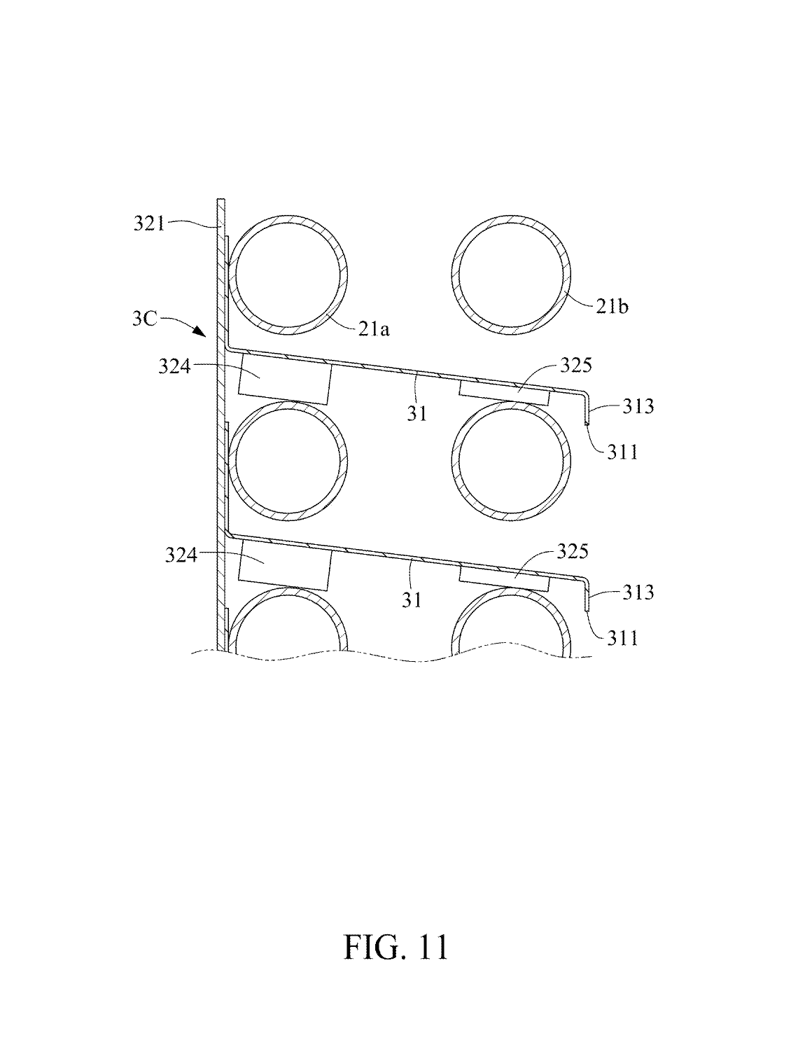

In FIG. 10 and FIG. 11, two sets of a first protrusion 324 and a second protrusion 325 are connected to the lower surface of each of the inclined plates 31, and the first protrusion 324 and the second protrusion 325 in each set are opposite to each other along a Y direction, but the present disclosure is not limited to this form. For example, in another possible embodiment, at least one set of the first protrusion 324 and the second protrusion 325 may also be arranged on lower surfaces of only a few of the inclined plates 31, and the first protrusion 324 and the second protrusion 325 in each set are not necessarily opposite to each other along the Y direction. Alternatively, since the connecting sheet 321 may assist in maintaining a spacing between the plurality of inclined plates 31, in the present disclosure, the first protrusion 324 may also be arranged on the lower surface of one of the inclined plates 31, and the second protrusion 325 is arranged on the lower surface of the other inclined plate 31, which can also achieve the foregoing effect.

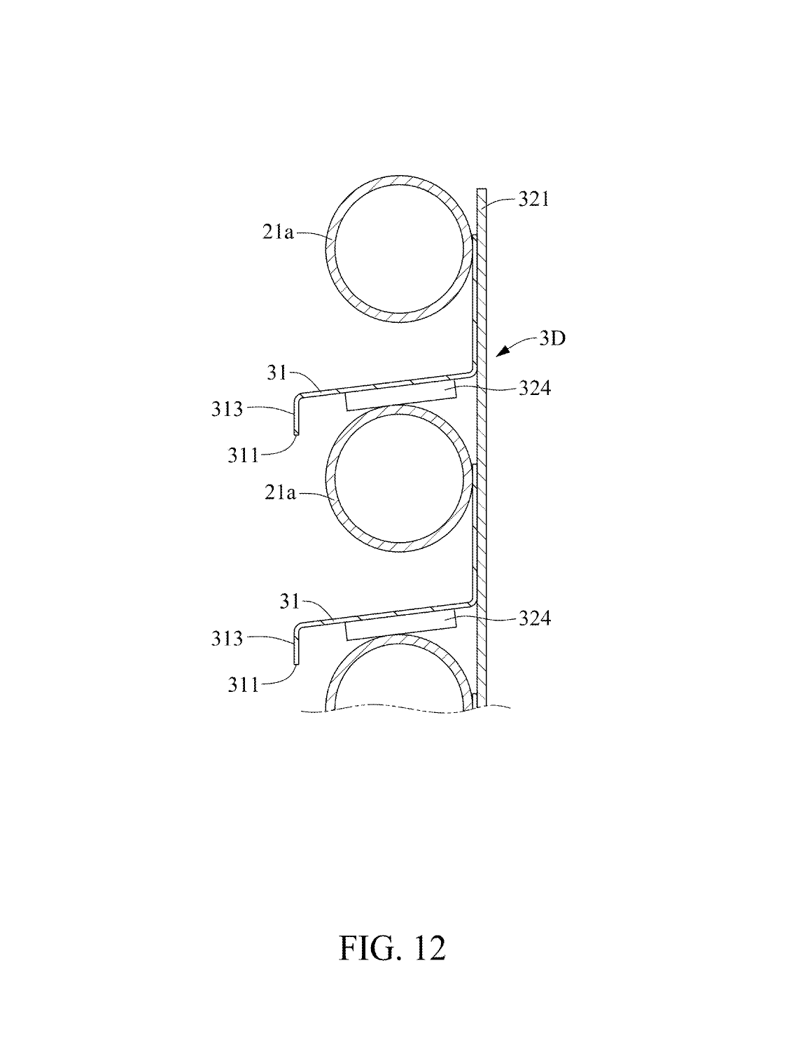

Referring to FIG. 9 and FIG. 12, a flow director 3D according to yet another embodiment of the present disclosure is disclosed. In this embodiment, the flow director 3D may match the form of the condensing module 2, and the inclined plate 31 is arranged to be in a form of extending from a high position to a low position by a shorter distance. The engagement portion 32 of the flow director 3D may have at least one connecting sheet 321 and at least one first protrusion 324. The connecting sheet 321 is connected to the plurality of inclined plates 31. The first protrusion 324 is connected to and protrudes from the lower surface of the inclined plate 31. In this way, during mounting of the flow director 3D, the plurality of inclined plates 31 may be aligned and inserted between a plurality of inner ring condenser tubes 21a specified in a longitudinal direction. The first protrusion 324 abuts against each of the inner ring condenser tubes 21a below.

It is worth mentioning that the flow director 3D of this embodiment may also be arranged in the condensing module 2 with only a single ring condenser tube 21 as shown in FIG. 2.

The present disclosure has been disclosed in the above with preferred embodiments. However, a person skilled in the art should understand that the embodiment is only used to illustrate the present disclosure, and should not be interpreted as a limitation on the scope of the present disclosure. It should be noted that all changes and substitutions equivalent to the embodiment should be considered to fall within the scope of the present disclosure. Therefore, the protection scope of the present disclosure is subject to the scope defined by the patent claims.

What is claimed is:

1. A two-phase cooling system, comprising:
a closed tank;
a condensing module, having a plurality of condenser tubes, wherein the plurality of condenser tubes are located above an interior of the closed tank and arranged longitudinally at intervals; and
a plurality of flow directors, wherein each of the flow directors has at least one inclined plate and at least one engagement portion, the engagement portion is connected to the inclined plate, the engagement portion is engaged with any one of the condenser tubes or the closed tank, and the inclined plate extends between two adjacent condenser tubes.

2. The two-phase cooling system according to claim 1, wherein the inclined plate has a liquid outlet end edge, and the liquid outlet end edge of the inclined plate is relatively adjacent to a tank wall of the closed tank.

3. The two-phase cooling system according to claim 1, wherein the inclined plate has a liquid outlet end edge, the condenser tube located below has an end edge on a same side as the liquid outlet end edge, and the liquid outlet end edge of the inclined plate protrudes beyond the end edge.

4. The two-phase cooling system according to claim 1, wherein the flow director has a plurality of inclined plates, and the engagement portion is simultaneously connected to the plurality of inclined plates.

5. The two-phase cooling system according to claim 4, wherein the engagement portion has a connecting sheet, a hook, and an abutting sheet, the connecting sheet is connected to the plurality of inclined plates, the hook is connected to the connecting sheet, the abutting sheet is connected to a liquid outlet end edge of one of the inclined plates, the hook hooks one of the condenser tubes, and the abutting sheet blocks an inner side or an outer side of another condenser tube.

6. The two-phase cooling system according to claim 5, wherein the connecting sheet abuts against an inner side of each of the plurality of condenser tubes, and the abutting sheet abuts against an outer side of one of the condenser tubes, or the connecting sheet abuts against an outer side of each of the plurality of condenser tubes, and the abutting sheet abuts against an inner side of one of the condenser tubes.

7. The two-phase cooling system according to claim 4, wherein the engagement portion has at least one connecting sheet and at least one first protrusion, the connecting sheet is connected to the plurality of inclined plates, the first protrusion is connected to and protrudes from a lower surface of each of the inclined plates, and the first protrusion abuts against a lower condenser tube.

8. The two-phase cooling system according to claim 1, wherein an inclined plate is configured between any two of the plurality of condenser tubes.

9. The two-phase cooling system according to claim 1, wherein the flow director has only a single inclined plate.

10. The two-phase cooling system according to claim 1, wherein the plurality of condenser tubes are divided into an inner ring condenser tube and an outer ring condenser tube, the outer ring condenser tube is located on a periphery of the inner ring condenser tube, a plurality of inclined plates are arranged, the engagement portion has at least one connecting sheet, at least one first protrusion, and at least one second protrusion, the connecting sheet is connected to the plurality of inclined plates, the first protrusion and the second protrusion are both connected to and protrude from a lower surface of each of the inclined plates, the first protrusion abuts against a lower inner ring condenser tube, and the second protrusion abuts against a lower outer ring condenser tube.

11. The two-phase cooling system according to claim 1, wherein the inclined plate is connected to a flow guide sheet extending downward at a lower inclined position.

12. A flow director, adapted to be configured in a two-phase cooling system, wherein the two-phase cooling system has a closed tank and a condensing module, the condensing module has a plurality of condenser tubes located above an interior of the closed tank and arranged longitudinally at intervals, and the flow director comprises:
at least one inclined plate; and
at least one engagement portion, wherein the engagement portion is connected to the inclined plate, the engagement portion is adapted to be engaged with any one of the condenser tubes or the closed tank, and the inclined plate is adapted to extend between two adjacent condenser tubes.

13. The flow director according to claim 12, wherein the inclined plate has a liquid outlet end edge, and the liquid outlet end edge is relatively adjacent to a tank wall of the closed tank.

14. The flow director according to claim 12, wherein the inclined plate has a liquid outlet end edge, the condenser tube located below has an end edge on a same side as the liquid outlet end edge, and the liquid outlet end edge of the inclined plate is adapted to protrude beyond the end edge.

15. The flow director according to claim 12, wherein a plurality of inclined plates are arranged, and the engagement portion is simultaneously connected to the plurality of inclined plates.

16. The flow director according to claim 15, wherein the engagement portion has a connecting sheet, a hook, and an abutting sheet, the connecting sheet is connected to the plurality of inclined plates, the hook is connected to the connecting sheet, the abutting sheet is connected to a liquid outlet end edge of one of the inclined plates, the hook is adapted to hook one of the condenser tubes, and the abutting sheet is adapted to block an inner side or an outer side of another condenser tube.

17. The flow director according to claim 16, wherein the connecting sheet is adapted to abut against an inner side of each of the plurality of condenser tubes, and the abutting sheet is adapted to abut against an outer side of one of the condenser tubes, or the connecting sheet is adapted to abut against an outer side of each of the plurality of condenser tubes, and the abutting sheet is adapted to abut against an inner side of one of the condenser tubes.

18. The flow director according to claim 15, wherein the engagement portion has at least one connecting sheet and at least one first protrusion, the connecting sheet is connected to the plurality of inclined plates, the first protrusion is connected to and protrudes from a lower surface of each of the inclined plates, and the first protrusion is adapted to abut against a lower condenser tube.

19. The flow director according to claim 12, wherein a single inclined plate is arranged.

20. The flow director according to claim 12, wherein the plurality of condenser tubes of the condensing module are divided into an inner ring condenser tube and an outer ring condenser tube, the outer ring condenser tube is located on a periphery of the inner ring condenser tube, a plurality of inclined plates are arranged, the engagement portion has at least one connecting sheet, at least one first protrusion, and at least one second protrusion, the connecting sheet is connected to the plurality of inclined plates, the first protrusion and the second protrusion are both connected to and protrude from a lower surface of each of the inclined plates, the first protrusion is adapted to abut against a lower inner ring condenser tube, and the second protrusion is adapted to abut against a lower outer ring condenser tube.

21. The flow director according to claim 12, wherein the inclined plate is connected to a flow guide sheet extending downward at a lower inclined position.
